(19) United States
(12) Patent Application Publication
(10) Pub. No.: US 2026/0333609 A1
(43) Pub. Date: Oct. 22, 2026

(54) SERVER DEVICE

(71) Applicants: INVENTEC (PUDONG) TECHNOLOGY CORPORATION, Shanghai (CN); INVENTEC CORPORATION, Taipei City (TW)

(72) Inventor: Chang-Hsin CHIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/468,082

(22) Filed: Feb. 3, 2026

Related U.S. Application Data
(60) Provisional application No. 63/768,321, filed on Mar. 7, 2025.

(30) Foreign Application Priority Data
May 20, 2025 (CN) 202510645039.7

(51) Int. Cl. H05K 7/14

(52) U.S. Cl. CPC H05K 7/1489

(57) ABSTRACT

A server device includes a carrier housing, a movable top cover, a front panel, an extended engaging component, and a latch component. The movable top cover is slidably assembled to the carrier housing and covers a portion of an accommodation space of the carrier housing. The front panel is fixed to the carrier housing and is located at a front opening of the accommodation space. The front panel and the movable top cover are respectively on adjacent sides of the accommodation space. The extended engaging component is fixed to the movable top cover and disposed within the accommodation space. The extended engaging component extends from the movable top cover toward the front opening and protrudes beyond a front edge of the movable top cover. The latch component is fixed to the front panel and corresponds to the extended engaging component. The latch component releasably engages the extended engaging component.

### CROSS-REFERENCE TO RELATED APPLICATIONS

This non-provisional application claims priority under 35 U.S.C. § 119(a) on Patent Application No(s). 202510645039.7 filed in China, on May 20, 2025 and U.S. Provisional Application 63/768,321, filed on Mar. 7, 2025, the entire contents of which are hereby incorporated by reference.

### BACKGROUND OF THE INVENTION

### Technical Field of the Invention

This invention relates to a server device, especially to a server device that is operable from a front end of a system to lock or unlock a top cover.

### Description of the Related Art

Currently, the top cover of a server is typically secured using components such as latch mechanisms, stainless steel spring clips, or thumbscrews. However, each of these methods has its limitations. Conventional latch mechanisms, while enabling quick release, occupy internal space and are not compatible with 1U and 2U server chassis configurations. Stainless steel spring clips offer structural simplicity but may suffer from elastic fatigue over time, thereby compromising long-term reliability. Thumbscrews require alignment with the opening/closing direction of the top cover, which makes them inconvenient for use with sliding-type covers.

Accordingly, there is a need to develop a top cover securing mechanism that is space-efficient, structurally robust, and compatible with various server chassis sizes. Such a design would improve design flexibility and facilitate maintenance operations in server systems.

### SUMMARY OF THE INVENTION

The invention provides a server device that addresses the issues of poor space utilization efficiency, insufficient structural stability, and incompatibility with various server chassis sizes in the prior art.

One embodiment of the invention provides a server device including a carrier housing, a movable top cover, a front panel, an extended engaging component, and a latch component. The carrier housing includes an accommodation space. The movable top cover is slidably assembled to the carrier housing and covers at least a portion of the accommodation space. The front panel is fixed to the carrier housing and is located at a front opening of the accommodation space, and the front panel and the movable top cover are respectively located on adjacent sides of the accommodation space. The extended engaging component is fixed to the movable top cover and disposed within the accommodation space, and the extended engaging component extends from the movable top cover toward the front opening and protrudes beyond a front edge of the movable top cover. The latch component is fixed to the front panel and disposed corresponding to the extended engaging component, and the latch component is configured to releasably engage the extended engaging component.

According to the server device as described above, by providing the extended engaging component on the movable top cover such that the extended engaging component extends from the movable top cover toward the front opening and protrudes beyond the front edge of the movable top cover, the extended engaging component can be correspondingly and releasably locked to the latch component disposed on the front panel. Therefore, the movable top cover can be reliably secured, while also enhancing the ease of operation and assembly efficiency for end users.

### BRIEF DESCRIPTION OF THE DRAWINGS

The invention will become more fully understood from the detailed description given hereinbelow and the accompanying drawings which are given by way of illustration only and thus are not limitative of The invention and wherein:

FIG. 1 is a perspective view of a server device in accordance with one embodiment of the invention;

FIG. 2 is an exploded view of the server device shown in FIG. 1;

FIG. 3 is a perspective view of an extended engaging component of the server device shown in FIG. 1;

FIG. 4 to FIG. 7 are partial cross-sectional schematic views illustrating an operation of a movable top cover and a latch component of the server device shown in FIG. 1; and

FIG. 8 is a partial cross-sectional schematic view of the server device shown in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

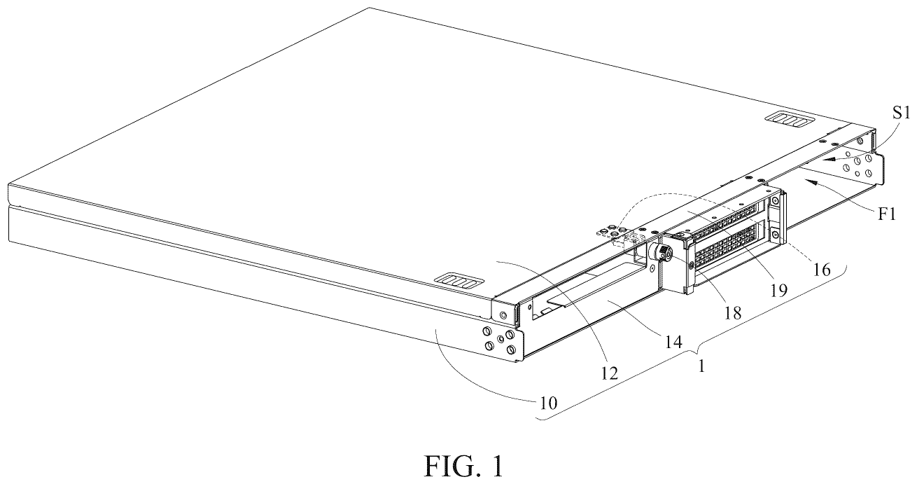

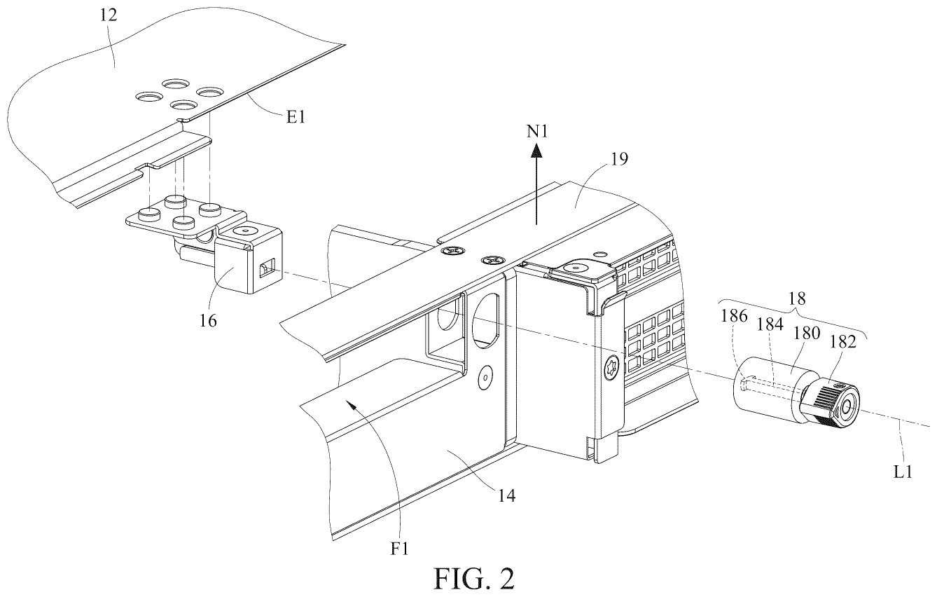

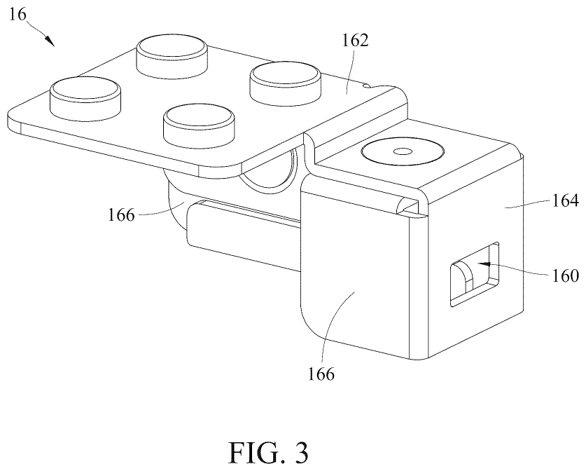

Referring to FIG. 1 to FIG. 3, FIG. 1 is a perspective view of a server device in accordance with one embodiment of the invention, FIG. 2 is an exploded view of the server device shown in FIG. 1, and FIG. 3 is a perspective view of an extended engaging component of the server device shown in FIG. 1.

In this embodiment, a server device 1 is provided. The server device 1 includes a carrier housing 10, a movable top cover 12, a front panel 14, an extended engaging component 16, and a latch component 18.

The carrier housing 10 includes an accommodation space S1, and a circuit board (not shown) is disposed within the accommodation space S1. The movable top cover 12 is slidably assembled to the carrier housing 10 and covers at least a portion of the accommodation space S1.

The front panel 14 is fixed to the carrier housing 10 and is located at a front opening F1 of the accommodation space S1. The front panel 14 and the movable top cover 12 are respectively located on adjacent sides of the accommodation space S1.

The extended engaging component 16 is fixed to the movable top cover 12 and disposed within the accommodation space S1. The extended engaging component 16 extends from the movable top cover 12 toward the front opening F1 and protrudes beyond a front edge E1 of the movable top cover 12.

The latch component 18 is fixed to the front panel 14 and disposed corresponding to the extended engaging component 16. The latch component 18 is configured to releasably engage the extended engaging component 16.

The server device 1 further includes a fixed cover plate 19, but the invention is not limited thereto. The fixed cover plate 19 is fixed to the carrier housing 10 and covers a portion of the accommodation space S1, and the fixed cover plate 19 is located between the movable top cover 12 and the front panel 14. The extended engaging component 16 extends from the movable top cover 12 into a region between the movable top cover 12 and the front panel 14, and the fixed cover plate 19 partially overlaps the extended engaging component 16 along a normal direction N1 of the fixed cover plate 19.

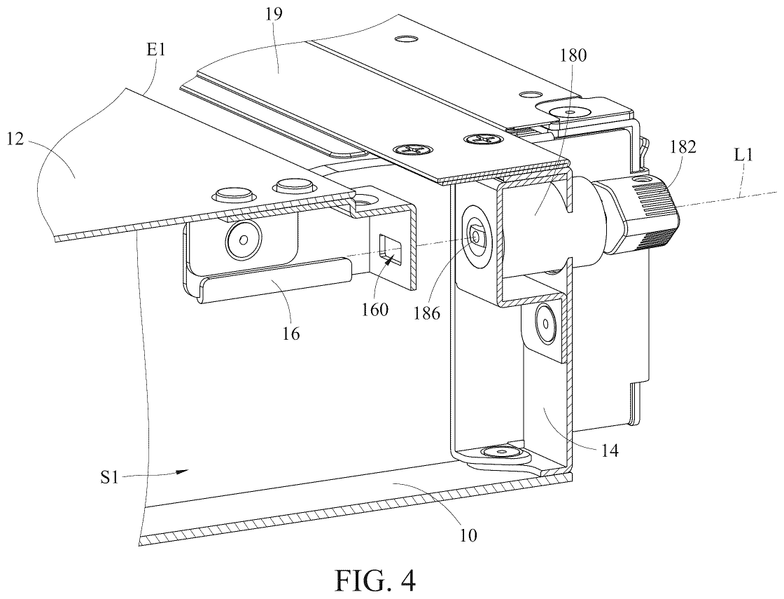

Please refer to FIG. 4 to FIG. 7, which are partial cross-sectional schematic views illustrating an operation of a movable top cover and a latch component of the server device shown in FIG. 1.

The extended engaging component 16 includes a latch hole 160 facing the front panel 14. The latch component 18 includes a mounting base 180, an operating portion 182, a pin 184, and a stopper portion 186. The mounting base 180 is fixed to the front panel 14. The operating portion 182 is rotatably disposed on the mounting base 180 about an axis L1 of the mounting base 180, and the operating portion 182 is located on a side of the front panel 14 opposite the accommodation space S1. The pin 184 is connected to the operating portion 182 and extends along the axis L1 through the mounting base 180 and the front panel 14 into the accommodation space S1. The pin 184 is releasably inserted into the latch hole 160. The stopper portion 186 is connected to an end of the pin 184 opposite the operating portion 182 and extends in a direction perpendicular to the axis L1.

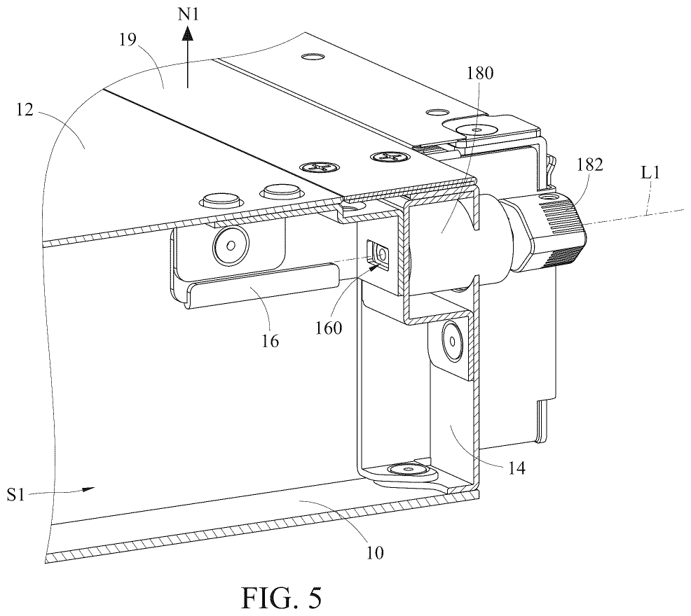

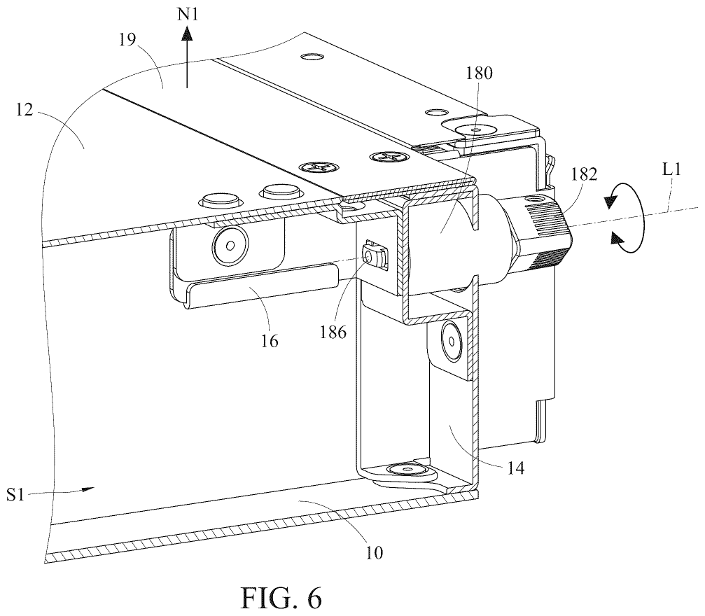

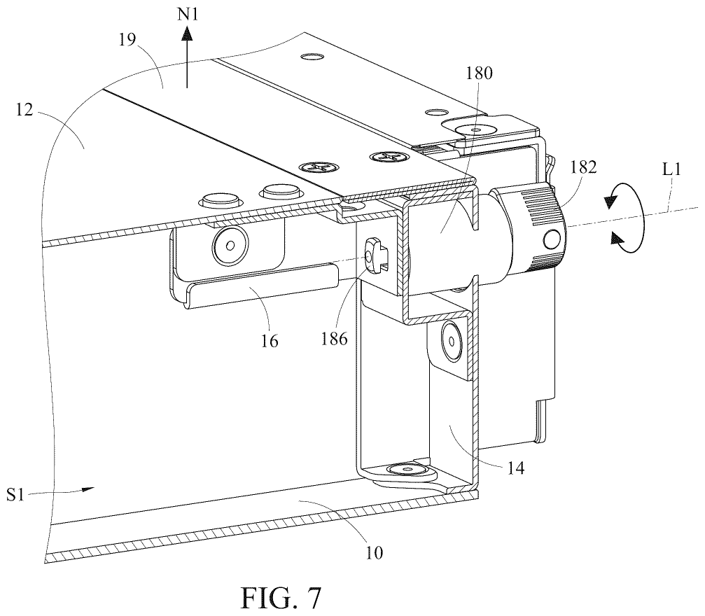

A length of the stopper portion 186 in a direction perpendicular to the axis L1 is greater than a width of the stopper portion 186 in a direction perpendicular to the axis L1. A hole length of the latch hole 160 is greater than a hole width of the latch hole 160. The length of the stopper portion 186 is smaller than the hole length and greater than the hole width of the latch hole 160, and the width of the stopper portion 186 is smaller than the hole width of the latch hole 160. As shown in FIG. 5 and FIG. 6, when the operating portion 182 is actuated to rotate the pin 184 and the stopper portion 186 to an unlocking position, a direction of the length of the stopper portion 186 is parallel to a direction of the hole length of the latch hole 160, such that the stopper portion 186 fully overlaps the latch hole 160 in the direction parallel to the axis L1; that is, the stopper portion 186 and a peripheral edge around the latch hole 160 do not interfere with each other in the direction parallel to the axis L1, such that the movable top cover 12 is not yet secured to the carrier housing 10. As shown in FIG. 7, when the operating portion 182 is actuated to rotate the pin 184 and the stopper portion 186 to a locking position, the direction of the length of the stopper portion 186 is not parallel to the direction of the hole length of the latch hole 160, such that the stopper portion 186 at least partially does not overlap the latch hole 160 in the direction parallel to the axis L1. That is, the stopper portion 186 and the peripheral edge around the latch hole 160 interfere with each other in the direction parallel to the axis L1, thereby securing the movable top cover 12 to the carrier housing 10.

The latch component 18 further includes a restoring component (not shown), but the invention is not limited thereto. The restoring component is connected to and located between the operating portion 182 and the mounting base 180, and the operating portion 182 is movably connected to the mounting base 180 via the restoring component in the direction parallel to the axis L1. As shown in FIG. 5 and FIG. 6, when the operating portion 182 drives the pin 184 and the stopper portion 186 to rotate to the unlocking position, the operating portion 182 is subjected to a restoring force of the restoring component, such that the operating portion 182 is moved in a direction away from the mounting base 180, thereby disengaging the pin 184 from the latch hole 160 (as shown in FIG. 5), or the operating portion 182 is subjected to an external force opposite to the restoring force, such that the operating portion 182 is moved toward the mounting base 180, thereby inserting the pin 184 into the latch hole 160 (as shown in FIG. 6). As shown in FIG. 7, when the operating portion 182 drives the pin 184 and the stopper portion 186 to rotate to the locking position, the operating portion 182 is subjected to a restoring force that is normally applied by the restoring component in a direction away from the mounting base 180, such that the stopper portion 186 abuts against the peripheral edge around the latch hole 160. In addition, the latch component 18 may be, for example, a quarter-turn automatic latch component, but the invention is not limited thereto.

As shown in FIG. 5 and FIG. 6, when the operating portion 182 is in the unlocking position and drives the pin 184 and the stopper portion 186 to move in the direction parallel to the axis L1, the pin 184 and the stopper portion 186 do not come into contact with the extended engaging component 16. Accordingly, the movable top cover 12 and the extended engaging component 16 are not pushed by the latch component 18, thereby preventing the movable top cover 12 from being unintentionally pushed open when the user operates the latch component 18.

The extended engaging component 16 further includes a top plate 162, a front wall 164, and two side walls 166. The top plate 162 is fixed to the movable top cover 12. The front wall 164 is connected to the top plate 162 and faces the front panel 14, and the latch hole 160 is located on the front wall 164. The two side walls 166 are connected to opposite sides of the top plate 162 and the front wall 164. In addition, the extended engaging component 16 is integrally formed by sheet metal bending, and the extended engaging component 16 is made of iron, but the invention is not limited thereto. Moreover, the extended engaging component 16 is riveted to the movable top cover 12, but the invention is not limited thereto.

In this embodiment and other embodiments of the invention, the latch hole 160 is rectangular, and the stopper portion 186 is a rectangular cuboid, but the invention is not limited thereto.

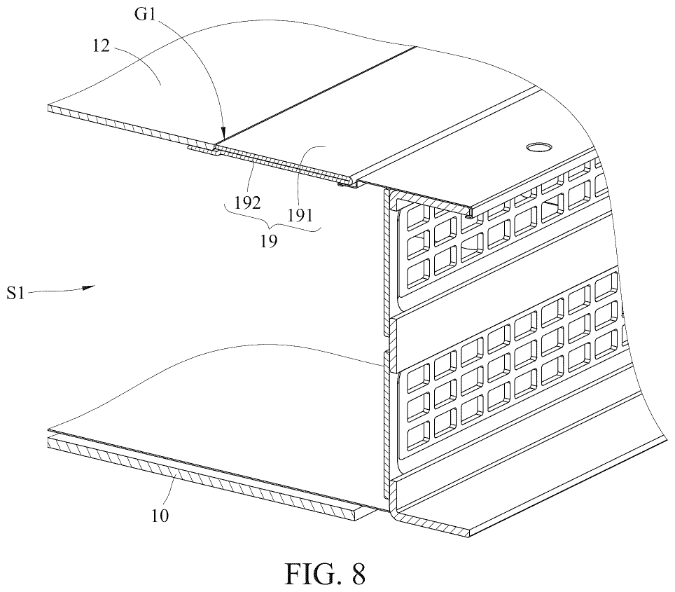

Please refer to FIG. 8, which is a partial cross-sectional schematic view of the server device shown in FIG. 1. A thickness of the movable top cover 12 is, for example, 0.8 millimeters (mm). The fixed cover plate 19 is, for example, formed by stacking an upper plate 191 and a lower plate 192, each having a thickness of 0.5 mm, and the upper plate 191 and the lower plate 192 are integrally formed by sheet metal bending. In the assembled state, the movable top cover 12 and the upper plate 191 of the fixed cover plate 19 are disposed side by side, and a gap G1 is formed between the movable top cover 12 and the upper plate 191. The lower plate 192 of the fixed cover plate 19 further bends and extends below the movable top cover 12. By configuring the lower plate 192 to extend below the movable top cover 12 so as to cover the gap G1 between the movable top cover 12 and the upper plate 191, electromagnetic interference (EMI) from the circuit board can be effectively prevented from leaking through the gap G1. In addition, since an internal space of the server device 1 is limited and a vertical distance between the movable top cover 12 and internal components is typically narrow, the thickness of the lower plate 192 of the fixed cover plate 19 is set to only 0.5 mm to prevent mechanical interference between the lower plate 192 and components below the movable top cover 12, while optimizing both shielding performance and spatial configuration. Furthermore, since the fixed cover plate 19 is formed by stacking the upper plate 191 and the lower plate 192, an overall stacked thickness is approximately 1 mm, ensuring sufficient structural strength of the fixed cover plate 19.

In this embodiment, the server device of the invention can be used for artificial intelligence (AI) computing, edge computing, and can also be used as a 5G server, a cloud server, or a server for vehicle-to-everything.

According to the server device as described above, by providing the extended engaging component on the movable top cover such that the extended engaging component extends from the movable top cover toward the front opening and protrudes beyond the front edge of the movable top cover, the extended engaging component can be correspondingly and releasably locked to the latch component disposed on the front panel. Therefore, the movable top cover can be reliably secured, while also enhancing the ease of operation and assembly efficiency for end users.

It will be apparent to those skilled in the art that various modifications and variations can be made to the invention. It is intended that the specification and examples be considered as exemplary embodiments only, with a scope of the invention being indicated by the following claims and their equivalents.

What is claimed is:

1. A server device comprising:
a carrier housing comprising an accommodation space;
a movable top cover slidably assembled to the carrier housing and covering at least a portion of the accommodation space;
a front panel fixed to the carrier housing and located at a front opening of the accommodation space, wherein the front panel and the movable top cover are respectively located on adjacent sides of the accommodation space;
an extended engaging component fixed to the movable top cover and disposed within the accommodation space, wherein the extended engaging component extends from the movable top cover toward the front opening and protrudes beyond a front edge of the movable top cover; and
a latch component fixed to the front panel and disposed corresponding to the extended engaging component, wherein the latch component is configured to releasably engage the extended engaging component.

2. The server device according to claim 1, further comprising a fixed cover plate, wherein the fixed cover plate is fixed to the carrier housing and covers a portion of the accommodation space, the fixed cover plate is located between the movable top cover and the front panel, the extended engaging component extends from the movable top cover into a region between the movable top cover and the front panel, and the fixed cover plate partially overlaps the extended engaging component along a normal direction of the fixed cover plate.

3. The server device according to claim 1, wherein the extended engaging component comprises a latch hole facing the front panel, the latch component comprises a mounting base, an operating portion, a pin, and a stopper portion, the mounting base is fixed to the front panel, the operating portion is rotatably disposed on the mounting base about an axis of the mounting base, the operating portion is located on a side of the front panel opposite the accommodation space, the pin is connected to the operating portion and extends along the axis through the mounting base and the front panel into the accommodation space, the pin is releasably inserted into the latch hole, and the stopper portion is connected to an end of the pin opposite the operating portion and extends in a direction perpendicular to the axis;
wherein a length of the stopper portion in a direction perpendicular to the axis is greater than a width of the stopper portion in a direction perpendicular to the axis, a hole length of the latch hole is greater than a hole width of the latch hole, the length of the stopper portion is smaller than the hole length and greater than the hole width of the latch hole, and the width of the stopper portion is smaller than the hole width of the latch hole;
wherein, when the operating portion is actuated to rotate the pin and the stopper portion to an unlocking position, a direction of the length of the stopper portion is parallel to a direction of the hole length of the latch hole, such that the stopper portion fully overlaps the latch hole in the direction parallel to the axis;
wherein, when the operating portion is actuated to rotate the pin and the stopper portion to a locking position, the direction of the length of the stopper portion is not parallel to the direction of the hole length of the latch hole, such that the stopper portion at least partially does not overlap the latch hole in the direction parallel to the axis.

4. The server device according to claim 3, wherein the latch hole is rectangular, and the stopper portion is a rectangular cuboid.

5. The server device according to claim 3, wherein the extended engaging component further comprises a top plate, a front wall, and two side walls, the top plate is fixed to the movable top cover, the front wall is connected to the top plate and faces the front panel, the two side walls are connected to opposite sides of the top plate and the front wall, and the latch hole is located on the front wall.

6. The server device according to claim 5, wherein the extended engaging component is integrally formed by sheet metal bending.

7. The server device according to claim 6, wherein the extended engaging component is made of iron.

8. The server device according to claim 1, wherein the extended engaging component is riveted to the movable top cover.
